(19) United States
(12) Patent Application Publication
(10) Pub. No.: US 2026/0354056 A1
(43) Pub. Date: Nov. 5, 2026

(54) HYDROGEN REGULATING GROWTH SUPPRESSION DEPOSITION FOR TUNGSTEN GAPFILL IN HIGH ASPECT RATIO STRUCTURE

(71) Applicant: Applied Materials, Inc., Santa Clara, CA (US)

(72) Inventors: Yang LI, Sunnyvale, CA (US); Peiqi WANG, Campbell, CA (US); Kai WU, Palo Alto, CA (US); Xinjing HUANG, Santa Clara, CA (US); Xiaozhou YU, Santa Clara, CA (US)

(21) Appl. No.: 19/197,748

(22) Filed: May 2, 2025

(51) Int. Cl. H10P 14/40; C23C 16/04; C23C 16/06

(52) U.S. Cl. CPC H10P 14/418; C23C 16/045; C23C 16/06

(57) ABSTRACT

In some embodiments, a method of forming a tungsten-containing structure in at least one opening of a multi-tier substrate in a processing chamber is provided. The method includes depositing a tungsten nucleation layer on surfaces of the at least one opening; and simultaneously exposing the at least one opening to a nitrogen-containing gas, a tungsten-containing gas, and a hydrogen-containing gapfill reducing agent gas to form a non-uniform passivation layer over the nucleation layer. The method further includes exposing the at least one opening to a hydrogen-rich ambient, and depositing a tungsten-containing material over the passivation layer

### BACKGROUND

### Field

Embodiments of the present disclosure generally relate to methods used in semiconductor device manufacturing, and more particularly, to methods used for forming tungsten features in a semiconductor device.

### Description of the Related Art

Tungsten is widely used as a conductive fill material in semiconductor device manufacturing, particularly in forming contacts, vias, and word lines for advanced three-dimensional (3D) memory devices. As device geometries have continued to scale and evolve, the introduction of complex, multi-tier architectures such as 3D NAND has posed new challenges. Conventional tungsten deposition methods, including chemical vapor deposition (CVD) and atomic layer deposition (ALD), typically yield conformal tungsten layers. While conformality can be beneficial in certain applications, it often leads to voids, seams, or incomplete fills within the narrow, deep openings encountered in high aspect ratio features.

Accordingly, there is a need for processes to fill contact features that are free or substantially free of voids and seams within channels in multi-tier structures.

### SUMMARY

The present disclosure generally relates to methods and systems for depositing tungsten-containing material into high aspect ratio structures of semiconductor devices. In particular, the disclosed techniques utilize hydrogen as a regulatory agent throughout various stages of tungsten deposition to achieve improved fill characteristics, enhanced adhesion, and controllable grain properties of the deposited tungsten-containing material.

In some embodiments, a method of forming a tungsten-containing structure in at least one opening of a multi-tier substrate in a processing chamber is provided. The method includes depositing a tungsten nucleation layer on surfaces of the at least one opening, and simultaneously exposing the at least one opening to a nitrogen-containing gas, a tungsten-containing gas, and a hydrogen-containing gapfill reducing agent gas to form a non-uniform passivation layer over the tungsten nucleation layer. The method further includes exposing the at least one opening to a hydrogen-rich ambient, and depositing a tungsten-containing material over the non-uniform passivation layer.

In some embodiments, a system for forming a tungsten-containing structure within at least one high aspect ratio feature of a substrate is provided. The system includes a processing chamber configured to hold the substrate having the at least one high aspect ratio feature, a gas delivery system coupled to the processing chamber, and a system controller coupled to the processing chamber and the gas delivery system. The system controller is programmed to cause the processing chamber and gas delivery system to perform a method. The method includes depositing a tungsten nucleation layer on surfaces of the at least one opening; and exposing the at least one opening to a nitrogen-containing gas, a tungsten-containing gas, and a hydrogen-containing gapfill reducing agent gas to form a non-uniform passivation layer over the nucleation layer. The nitrogen-containing gas is flowed into the processing chamber at about 0.5 sccm to about 500 sccm, the tungsten-containing gas is flowed into the processing chamber at about 150 sccm to about 600 sccm, and the hydrogen-containing gapfill reducing agent gas is flowed into the processing chamber at about 1000 sccm to about 8000 sccm. The method further includes exposing the at least one opening to a hydrogen-rich ambient, and depositing a tungsten-containing material over the passivation layer.

In some embodiments, a method of forming a tungsten-containing structure in at least one opening of a multi-tier substrate in a processing chamber is provided. The method includes depositing a tungsten nucleation layer on surfaces of the at least one opening, and forming a non-uniform passivation layer over the nucleation layer, wherein the passivation layer is thicker at a top portion of the at least one opening than at a bottom portion of the at least one opening. The method further includes depositing a tungsten-containing material over the passivation layer, exposing the tungsten-containing material to a hydrogen-rich ambient, and depositing additional tungsten-containing material into the at least one opening.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic sectional view of a portion of a substrate having a multi-tier structure, illustrating the formation of voids and seams in tungsten structures produced by conventional deposition processes.

FIG. 2 is a schematic view of an exemplary substrate processing system that can be used to implement the methods described herein, according to some embodiments.

FIG. 3A is a simplified diagram illustrating a process flow for minimizing voids, enhancing adhesion, and controlling grain size within high aspect ratio features during gap filling procedures.

FIG. 3B is a simplified graph of process conditions during the process flow of FIG. 3A.

FIGS. 4A-4D are schematic sectional views of a portion of a substrate 400 illustrating aspects at different stages of the void-free and seam-free tungsten gapfill process flow 300A.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments herein are generally directed to systems and methods for forming low resistivity tungsten features in semiconductor device manufacturing schemes using growth suppression techniques.

As noted above, tungsten (W) is widely used as a conductive fill material in semiconductor device manufacturing, particularly in forming contacts, vias, and word lines for advanced three-dimensional (3D) memory devices. As device geometries have continued to scale, the introduction of complex, multi-tier architectures such as 3D NAND has posed new challenges. Conventional tungsten deposition methods, including chemical vapor deposition (CVD) and atomic layer deposition (ALD), typically yield conformal tungsten layers. While conformality can be beneficial in certain applications, it often leads to voids, seams, or incomplete fills within the narrow, deep openings encountered in high aspect ratio features.

Further, conventional tungsten gap filling processes do not readily support fine-tuning of the tungsten grain structure without affecting other properties of deposited materials. Larger grains may enhance certain electrical characteristics but can affect film stability, while smaller grains may improve mechanical integrity but potentially increase resistivity. Balancing these trade-offs is a key consideration for the overall fabrication of a device structure.

Growth suppression deposition (GSD) techniques, which can include a nitrogen-containing treatment, can be used to promote a bottom-up fill behavior. Through the promotion of bottom-up fill behavior, such techniques thereby reduce void formation and improve overall fill quality of deposited tungsten-containing materials. Yet, treatment agents used during GSD techniques can lead to unintended etching of underlying surfaces, particularly under high-temperature conditions, thereby affecting deposited layer stability and raising concerns about film adhesion.

The present disclosure provides improved GSD techniques that include a modified flow of hydrogen and a dedicated hydrogen soak, which enable control of undesired etching caused by GSD treatment agents and improve the adhesion of deposited materials. Further, the techniques described herein facilitate control in grain size and film non-uniformity of deposited tungsten-containing materials. Accordingly, the present disclosure provides improved systems and methods to enhance overall tungsten gap fill performance in advanced, high aspect ratio 3D NAND structure and/or similar structures.

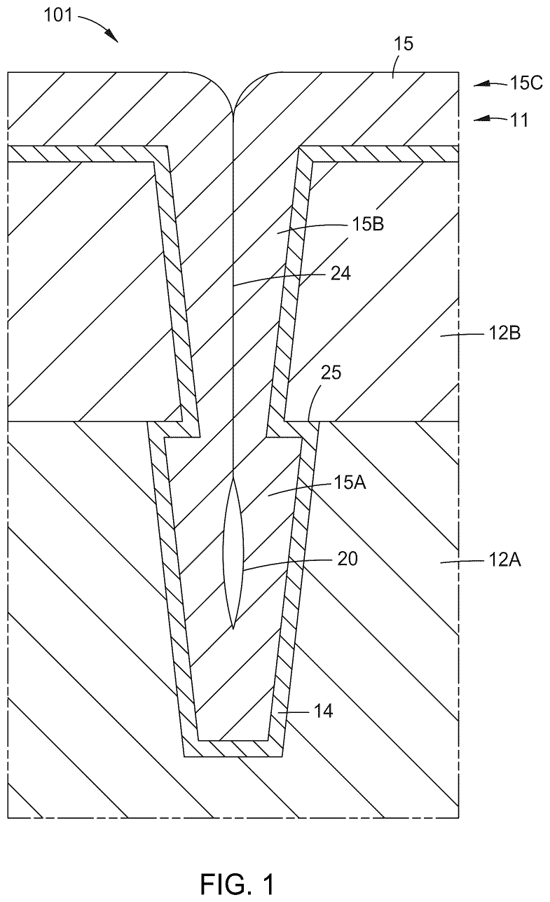

FIG. 1 is a schematic cross-sectional view of a substrate 101 illustrating an undesirable void 20 formed during a conventional tungsten deposition process. Here, the substrate 101 includes a patterned surface 11 disposed within a plurality of tier layers, such as a first tier layer 12A and a second tier layer 12B. In some embodiments, the first tier layer 12A is a first dielectric layer, e.g., silicon oxide (SiOₓ), and the second tier layer 12B is a second dielectric layer, e.g., silicon nitride (SiN). In some embodiments, the substrate 101 includes a plurality of alternating first and second tier layers 12A and 12B. The patterned surface 11 includes at least one opening having a high aspect ratio opening formed therein (shown filled with a portion of a tungsten layer 15), a barrier material layer 14 deposited on the first tier layer 12A and second tier layer 12B to line the opening, and the tungsten layer 15 deposited on the barrier material layer 14. The tungsten layer 15 illustrated in FIG. 1 is formed using a conventional deposition process, e.g., a chemical vapor deposition (CVD) or atomic layer deposition (ALD) process, where tungsten is conformally deposited (grown) on the patterned surface 11 to fill the opening. The tungsten layer 15 forms a tungsten feature 15A within the first tier layer 12A, a tungsten feature 15B within the second tier layer 12B and an overburden of material (tungsten overburden layer 15C) on the field of the patterned surface 11.

In FIG. 1, the opening has a non-uniform profile that is wider at the surface of the substrate 101 and tapers as the opening extends from the surface inwardly into the second tier layer 12B. At an interface 25 of the first and second tier layers, the width of the second tier layer 12B is narrower than the width of the first tier layer 12A disposed inward from the second tier layer 12B. As shown, interface portions of the tungsten layer 15 have grown together to block or “pinch off” the entrance to the opening disposed in the first tier layer 12A before the opening could be completely filled, thus causing the void 20, i.e., an absence of tungsten material, in the tungsten feature 15A. In addition to voids, undesirable seams 24 can occur in tungsten features, as shown within the second tier layer 12B, using a conventional tungsten deposition process.

The presence of voids 20 and seams 24 can be problematic as they can lead to compromised device performance. Voids 20 and seams 24 may act as sites for unwanted chemical attack during subsequent processing operations, such as during planarization or cleaning, resulting in tungsten loss and increased electrical resistance. For example, the void 20 and seam 24 may be vulnerable to corrosion from chemically active components of a tungsten chemical mechanical polishing (CMP) polishing fluid, which may cause undesirable loss of tungsten material from the tungsten features 15A, 15B if the seam 24 or void 20 is exposed during a CMP process. Additionally, these defects can hinder the reliable integration of tungsten-filled features or tungsten-containing structures in advanced semiconductor architectures, where feature aspect ratios may exceed 50:1, 80:1, or even 100:1.

Accordingly, embodiments herein provide systems and methods that address the above shortcomings of convention conformal tungsten growth techniques, thus improving the deposition of a tungsten-containing material within high aspect ratio features with a more desirable bottom-up fill. The methods and systems provided herein are particularly useful for tungsten gapfill for high aspect ratio features, such as about 25:1 or greater, such as about 30:1 to about 150:1, such as about 50:1 to about 80:1. The aspect ratio refers to a ratio of total height to an average width or diameter of the feature.

Generally, the gapfill processing schemes described herein include forming a differential tungsten growth suppression deposition (GSD) profile in feature openings formed in a surface of a substrate, filling the openings with tungsten material according to the GSD profile, and depositing an overburden of tungsten on the field surface of the substrate. Forming the tungsten GSD profile typically includes forming a tungsten nucleation layer and then exposing the tungsten nucleation layer to a GSD gas including a nitrogen-containing gas, a tungsten-containing gas, and a gapfill reducing agent. The nitrogen-containing gas can further include molecules including hydrogen atoms, fluorine atoms, or combinations thereof, such as nitrogen trifluoride, NH3, N2H4, or combinations thereof. The nitrogen from the nitrogen-containing gas is incorporated into portions of the nucleation layer, e.g., by adsorption of the nitrogen or by reaction with the metallic tungsten of the nucleation layer to form a tungsten nitride (WN) passivation layer. The adsorbed nitrogen or nitrided surface of the tungsten nucleation layer desirably delays (inhibits) tungsten nucleation and thus subsequent tungsten deposition thereon. The tungsten-containing gas, such as tungsten fluoride, and the reducing agent, such as hydrogen gas, when co-flowed with the nitrogen-containing gas, consume the nitrogen containing gas as/before it reaches the bottom of the multi-tier structure, producing a gradient or non-uniformly deposited tungsten nitride passivation layer. Alternatively, different combinations of co-flowed gases, e.g., the hydrogen gas and the tungsten containing gas, are co-flowed with the nitrogen-containing gas to produce the nonuniformly deposited tungsten nitride passivation layer.

The resulting non-uniformly deposited passivation layer has the greatest thickness at the top of the structure, e.g., the top opening, and a decreasing thickness further into the structure. This approach helps inhibit tungsten nucleation more strongly at the upper regions, reducing pinch-off, while allowing preferential bottom-up fill in deeper areas. As a result, the feature opening can fill uniformly from its lowest regions upward, minimizing voids and improving overall film quality of deposited materials.

In some embodiments, the gapfill processing schemes described herein include increasing hydrogen flow during the GSD treatment and/or a portion of a bulk tungsten deposition operation, which suppresses unwanted etching of the deposited passivation layer from residual fluorine. In some embodiments, one or more hydrogen soaks are strategically performed between bulk depositions of the tungsten-containing material, which further improves adhesion between the deposited tungsten and underlying surfaces of the substrate, and also enables control over tungsten grain size. The hydrogen soak(s) also remove residual fluorine left over from the GSD operation, thereby preventing further etching thereby. As a result, implementing the above GSD approach with regulated hydrogen parameters can mitigate formation of the void 20 and seam 24, enabling more reliable and robust tungsten features, even in challenging multi-tier and high aspect ratio structures, than those obtained via conventional methods such as that illustrated in FIG. 1.

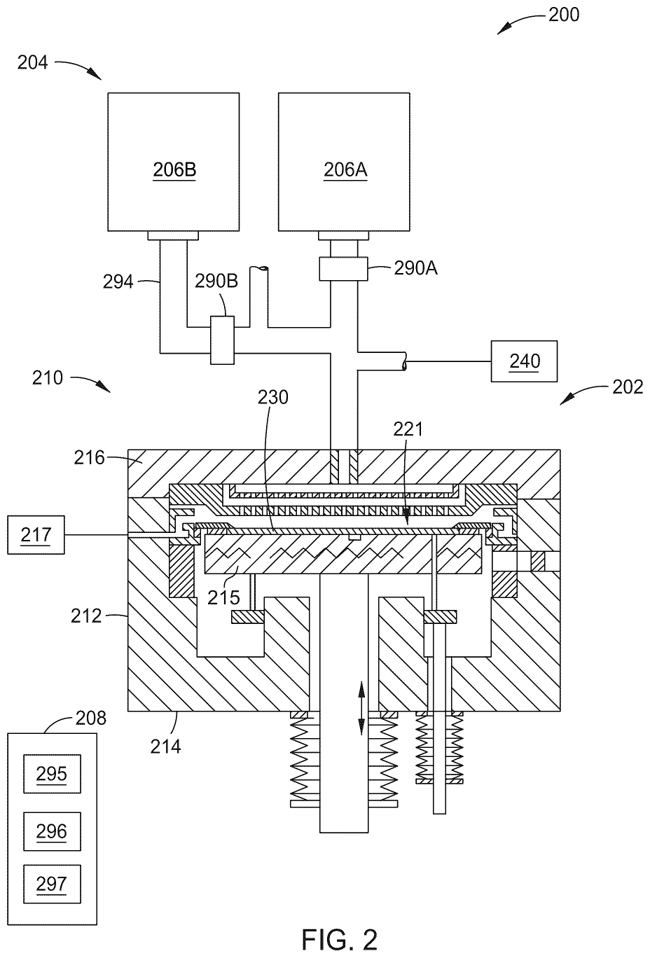

FIG. 2 is a schematic illustration of an exemplary substrate processing system 200 configured to carry out the bottom-up tungsten deposition processing methods discussed herein, including nucleation, tungsten bulk deposition, and intermediate hydrogen soaks, all within a single processing environment. By integrating all necessary processes, ranging from establishing a nucleation layer to introducing a passivation layer with increased hydrogen flow, performing hydrogen soak intervals, and depositing bulk tungsten, the substrate processing system 200 enables a more controlled and efficient process flow compared to conventional multi-chamber setups.

The substrate processing system 200 includes a processing chamber 202. This processing chamber 202, which can be adapted for fabrication of three-dimensional (3D) NAND or similarly complex device architectures, is coupled to a gas delivery system 204 and is overseen by a system controller 208. The processing chamber 202 includes a chamber lid assembly 210, one or more sidewalls 212, and a chamber base 214 that together at least partially define a processing volume 221. A substrate 230 (e.g., a semiconductor wafer bearing high aspect ratio features such as trenches or vias) is supported on a substrate support pedestal 215, which may include temperature control elements and electrostatic clamping mechanisms to ensure stable and uniform processing conditions.

Operation of the substrate processing system 200 is facilitated by the system controller 208. The system controller 208 includes a programmable central processing unit (CPU), here the CPU 295, which is operable with a memory 296 (e.g., non-volatile memory) and support circuits 297. The CPU 295 is one of any form of general-purpose computer processors used in an industrial setting, such as a programmable logic controller (PLC), for controlling various chamber components and sub-processors. The memory 296, coupled to the CPU 295, facilitates the operation of the processing chamber. The support circuits 297 are conventionally coupled to the CPU 295 and comprise cache, clock circuits, input/output subsystems, power supplies, and the like, and combinations thereof coupled to the various components of the substrate processing system 200 to facilitate control of substrate processing operations therewith.

The instructions in memory 296 are in the form of a program product, such as a program that implements the methods of the present disclosure. In one example, the disclosure may be implemented as a program product stored on computer-readable storage media for use with a computer system. The programs of the program product define functions of the embodiments including the methods described herein. Thus, the computer-readable storage media, when carrying computer-readable instructions that direct the functions of the methods described herein, are embodiments of the present disclosure.

The substrate processing system 200 described above can be used to perform each of the nucleation, GSD treatment, bulk tungsten deposition, and hydrogen soak, thus providing a single-chamber seam-free tungsten gapfill solution.

The gas delivery system 204 introduces various process gases into the processing volume 221. It may include multiple gas lines, mass flow controllers, and at least one deposition gas source 240 containing tungsten-containing precursors (e.g., WF₆), reducing agents (e.g., H₂), and optionally nitrogen-containing gases (e.g., NF₃) used during the GSD process. A conduit system 294 routes these gases into the chamber lid assembly 210, often equipped with a showerhead or gas distribution plate, ensuring uniform delivery across the substrate surface. The processing volume 221 is further fluidly coupled to an exhaust 217, allowing the removal of by-products and maintaining the chamber at desired sub-atmospheric pressures conducive to tungsten deposition.

To enable advanced GSD techniques, the gas delivery system 204 may also include one or more remote radical or plasma generators, illustrated as the first radical generator 206A and the second radical generator 206B. These generators can activate certain gases into more reactive species, enhancing passivation layer formation or chamber cleaning. Isolation valves 290A and 290B are interposed between the radical generators 206A, 206B and a chamber lid plate 216 of the chamber lid assembly 210, permitting selective fluid isolation to protect sensitive components or to streamline transitions between different process modes. For instance, the isolation valves 290A,290B can be closed to prevent halogen radicals from entering the radical generators during chamber clean cycles, preserving generator component integrity.

In some embodiments, the gas delivery system 204 includes an additional source, or reservoir, for nitrogen-containing gases (e.g., NF₃). Such reservoir can be in fluid communication with an isolation valve disposed between the reservoir and the chamber lid plate 216. The reservoir can be charged, or filled, with nitrogen-containing gas and/or argon gas, and then discharged, or emptied into the processing volume 221, by adjustment of the isolation valve to enable price control of nitrogen-containing gases introduced into the processing volume 221 during the methods described herein.

Because the tungsten deposition methods described herein involve carefully balancing multiple parameters, hydrogen flow, soak times, precursor delivery rates, and temperature, a system capable of tight controlled interaction and integration among these parameters is essential. Such precise control is particularly important for achieving reliable bottom-up fill while optimizing the tungsten film's adhesion, morphology, fluorine content, and electrical properties.

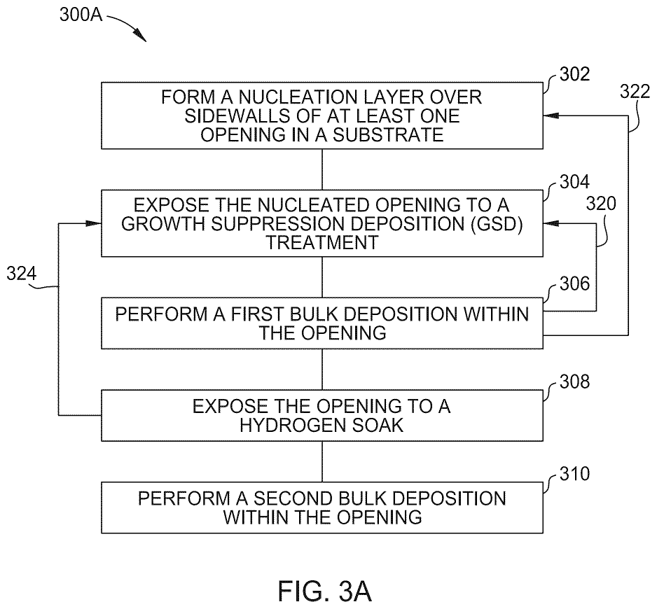

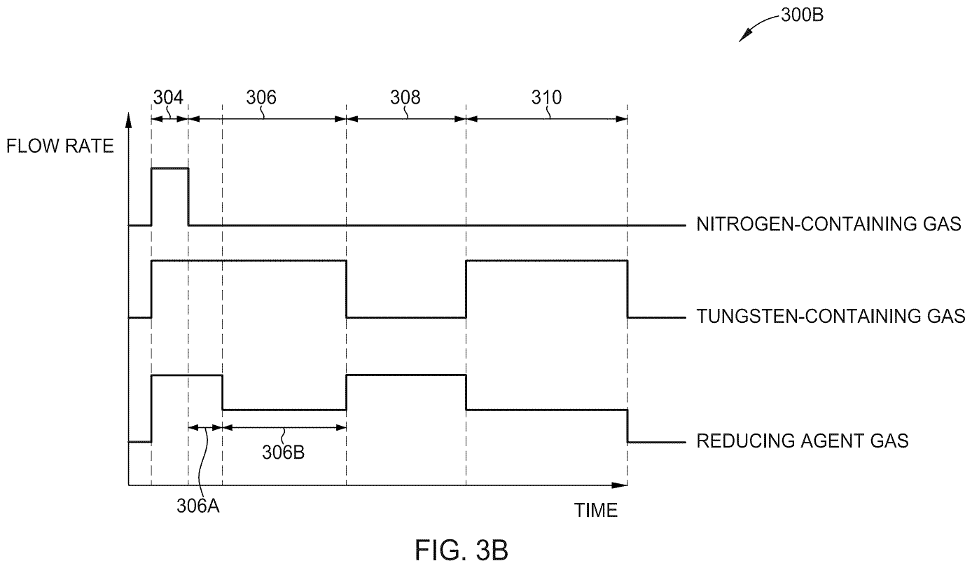

FIG. 3A illustrates a simplified diagram of an exemplary process flow 300A for achieving improved tungsten gapfill in high aspect ratio features using the hydrogen-regulated growth suppression deposition (GSD) techniques described above. FIG. 3B illustrates a graph 300B comparing relative gas flow rate changes during various blocks of the process flow 300A. For clarity, FIGS. 3A and 3B are herein described together.

As shown, the process flow 300A includes blocks 302, 304, 306, 308, and 310. Although depicted in a particular order, the blocks 302-310 can be performed in any suitable order, and any number of blocks 302-310 can be repeatedly performed in a single process flow.

At block 302, a tungsten nucleation layer is formed over sidewalls of one or more openings in a substrate (e.g., substrate 230) using any suitable process. The nucleation layer can be formed using an atomic layer deposition (ALD) process or a physical vapor deposition (PVD) process.

Generally, forming the nucleation layer includes exposing the substrate 230 to a tungsten-containing precursor gas introduced to the processing chamber 200 at a first precursor gas flow rate. In some embodiments, forming the nucleation layer includes exposing the substrate 230 to a nucleation reducing agent introduced to the processing chamber 200 at a nucleation reducing agent flow rate. The nucleation reducing agent can include boron. In some embodiments, the tungsten-containing precursor gas and the nucleation reducing agent are alternated cyclically to form a nucleation layer over the substrate 230 within at least one opening of the substrate 230 at the nucleation reducing agent flow rate. In some embodiments, the nucleation reducing agent and the tungsten-containing precursor gas are cyclically alternated, beginning with either the nucleation reducing agent or the tungsten-containing precursor, and ending with the same beginning gas or ending with a gas different from the beginning gas. In some embodiments, the nucleation reducing agent or the tungsten-containing precursor are cyclically alternated beginning with tungsten-containing precursor and ending in the nucleation reducing agent.

In some embodiments, the nucleation layer is deposited using an atomic layer deposition (ALD) process, which can include repeating cycles of alternately exposing the substrate 230 to a tungsten-containing precursor and/or other precursor and exposing the substrate 230 to a nucleation reducing agent. In some embodiments, the processing region 221 of the processing chamber 200 is purged between the alternating exposures. In some embodiments, the processing region 221 is continuously purged. The processing region 221 can be purged by flowing a purge gas, such as argon (Ar) or hydrogen gas, into the processing region 221.

Examples of suitable tungsten-containing precursors include tungsten halides, such as tungsten hexafluoride (WF₆), tungsten hexachloride (WCl₆), or combinations thereof. In some embodiments, the tungsten-containing precursor includes WF_{6,} and the nucleation reducing agent includes a boron-containing agent, such as B₂H₆. In some embodiments, the tungsten-containing precursor comprises an organometallic precursor or a fluorine-free precursor, e.g., MDNOW (methylcyclopentadienyl-dicarbonyInitrosyl-tungsten), EDNOW (ethylcyclopentadienyl-dicarbonyInitrosyl-tungsten), tungsten hexacarbonyl (W(CO)₆), tungsten hexachloride (WCl₆), or combinations thereof. In some embodiments, the ALD precursors include silane (SiH₄).

Exposing the substrate 230 to the tungsten-containing precursor can include flowing the tungsten-containing precursor into the processing region 221 from the deposition gas source 240 at a flow rate of about 1000 sccm or less, such as about 10 sccm to about 500 sccm, or about 20 sccm to about 200 sccm. Exposing the substrate 230 to the nucleation reducing agent can include flowing the nucleation reducing agent into the processing region 221 from the deposition gas source 240 at a flow rate of about 200 sccm to about 1000 sccm, such as between about 300 sccm and about 750 sccm. It should be noted that the flow rates for the various deposition and treatment processes described herein are for a substrate processing system 200 configured to process a 300 mm diameter substrate 230. Appropriate scaling can be used for processing systems configured to process different-sized substrates.

The tungsten-containing precursor and the nucleation reducing agent can be each flowed into the processing region 221 for a duration of between about 0.1 seconds and about 10 seconds, such as between about 0.5 seconds and about 5 seconds. The processing region 221 can be purged between the alternating exposures by flowing a purge gas, such as argon or hydrogen gas, into the processing region 221 for a duration of between about 0.1 seconds and about 10 seconds, such as between about 0.5 seconds and about 5 seconds. The purge gas can be delivered from the deposition gas source 240 or from a bypass gas source (not shown).

During the nucleation process, the processing volume 221 can be maintained at a pressure of less than about 150 Torr, such as between about 1 Torr and about 50 Torr, between about 1 Torr and about 100 Torr, or for example, between about 15 Torr and about 150 Torr.

Typically, repeating cycles of the nucleation process can be performed until the nucleation layer has a thickness of between about 10 Å and about 200 Å, such as between about 10 Å and about 150 Å, or between about 20 Å and about 150 Å. The nucleation layer is generally disposed along sidewalls of the opening(s) in the substrate 230.

In some embodiments, prior to forming the nucleation layer, the substrate 230 is exposed to a boron-containing gas, such as B₂H₆, for a soak time of about 5 seconds or greater, such as about 10 seconds or greater, such as about 20 seconds to 30 seconds. In some embodiments, the nucleation layer is deposited over another layer formed over the sidewalls of the opening(s), such as an adhesion layer or a barrier layer. In such embodiments, the barrier can include titanium nitride (TiN), tungsten nitride (WNₓ), tantalum nitride (TaN), or another suitable material that promotes bonding between underlying dielectric layers of the substrate 230 and subsequently formed tungsten films.

At block 304, a growth suppression deposition (GSD) treatment is performed to facilitate formation of a differential tungsten GSD profile in the nucleated opening(s) of the substrate 230.

Forming a tungsten GSD profile generally includes exposing the tungsten nucleation layer to a GSD gas mixture including a nitrogen-containing gas, a tungsten-containing gas, and a gapfill reducing agent. The nitrogen-containing gas can further include molecules including hydrogen atoms, fluorine atoms, or combinations thereof, such as nitrogen trifluoride, NH₃, N₂H₄, or combinations thereof. The nitrogen from the nitrogen-containing gas is incorporated into portions of the previously formed nucleation layer, e.g., by adsorption of the nitrogen or by reaction with the metallic tungsten of the nucleation layer, which can form a tungsten nitride (WN) passivation layer. The adsorbed nitrogen or nitrided surface of the tungsten nucleation layer desirably delays (inhibits) tungsten nucleation and thus subsequent tungsten deposition thereon. The tungsten-containing gas, such as tungsten fluoride, and the reducing agent, such as hydrogen gas, when co-flowed with the nitrogen-containing gas, consume the nitrogen-containing gas as/before it reaches the bottom of the nucleated opening, producing a favorable passivation gradient, or non-uniformly deposited tungsten nitride passivation layer inside the structure, wherein the passivation layer is thickest at a top portion of the nucleated opening. This gradient suppresses subsequent tungsten deposition/growth in upper regions of the opening(s) while favoring tungsten growth at the lower portions first, effectively driving a bottom-up fill, as opposed to a conformal fill, and helps mitigate the formation voids or premature pinch-off in high aspect ratio structures.

Accordingly, the GSD treatment at block 304 includes co-flowing, simultaneously, a nitrogen-containing gas (e.g., NF₃), a tungsten-containing precursor (e.g., WF₆), and a reducing agent, such as hydrogen (e.g., H₂), into the processing chamber 200 under selected temperature, pressure, and flow-rate conditions.

In some embodiments, the nitrogen-containing gas, the tungsten-containing gas, and the gapfill reducing agent gas are co-flowed into the processing region 221 (e.g., flowed into the processing region 221 at the same time, or simultaneously) at block 304 for a duration of about 0.1 to about 5 seconds, such as between about 0.1 seconds and about 3 seconds, such as between about 0.1 seconds and about 1 second, such as between about 0.1 seconds and about 0.5 seconds, such as between about 0.1 seconds and about 0.3 seconds. In some embodiments, the nitrogen-containing gas is co-flowed at the same time as the gapfill reducing agent gas, before flowing the tungsten-containing gas and gapfill reducing-agent gas together without the nitrogen-containing gas. In some embodiments, the nitrogen-containing gas can also be co-flowed with the tungsten-containing gas before flowing the tungsten-containing gas and gapfill reducing agent gas without the nitrogen-containing gas.

In some embodiments, nitrogen-containing gas is flowed into the processing region 221 at a flow rate of about 0.5 sccm to about 1000 sccm, such as about 0.5 sccm to about 1000 sccm, such as about 10 sccm to about 500 sccm, about 300 sccm to about 500 sccm, or about 600 sccm to about 800 sccm. In some embodiments, the nitrogen-containing gas is combined with an inert carrier gas, such as Ar, He, or a combination thereof, to form a nitrogen-containing gas mixture. Alternatively, the nitrogen-containing gas may be flowed into the processing volume 221 without the carrier gas, e.g., introducing a flow of the pure nitrogen-containing gas. For example, pure NF₃ may be flowed into the processing volume 221 as part of the gsd gas mixture without Ar as a carrier gas. Removing the carrier gas from the nitrogen-containing gas can further extend the process window with a stronger incubation while lowering resistivity. The flow rate of the nitrogen-containing gas is controlled and may be pulsed by a diaphragm valve, e.g., the first valve 294A, to provide precise control of its dosage into the processing volume and to control thickness of the subsequent tungsten nitride passivation layer.

In some embodiments, the tungsten-containing gas is flowed at a flow rate of about 150 sccm to 600 sccm, such as about 200 sccm to about 500 sccm, or about 300 sccm to about 440 sccm. In some embodiments, the tungsten-containing gas is flowed at a flow rate of about 300 sccm, or a flow rate of about 450 sccm, or a flow rate of about 600 sccm.

In some embodiments, the gapfill reducing agent gas, such as hydrogen (H₂) gas, is flowed at a flow rate of about 1000 sccm to about 8000 sccm, such as about 2000 sccm to about 6000 sccm, or about 3000 sccm to about 5000 sccm. This creates a hydrogen-to-tungsten precursor ratio of about 13:1 to about 53:1, which is optimal for suppressing unwanted etching of the deposited tungsten nitride passivation layer from residual fluorine in the processing chamber 221. As noted above, increased flow of hydrogen during the GSD treatment at block 304, as compared to the nitrogen-containing gas and/or the tungsten-containing gas, suppresses and/or eliminates unwanted etching of the passivation layer from residual fluorine species.

In some embodiments, the temperature of the substrate 230 at block 304 is maintained at about 200 °C to about 600 °C, such as about 300 °C to about 500 °C, or about 400 °C to about 500 °C. In some embodiments, during the GSD treatment, the processing volume 221 can be maintained at a pressure of about 15 Torr to 150 Torr, such as between about 20 Torr and about 100 Torr, or for example, between about 40 Torr and about 80 Torr. In some embodiments, the processing volume 221 is maintained at a pressure of about 90 T and about 120 T.

As noted above, the GSD treatment at block 304 can create better nitrogen-containing gas gradients inside the opening(s) of the substrate 230, resulting in more desirable passivation layer gradients on their sidewalls. As the nitrogen-containing gas travels down the opening, its local concentration diminishes due to reaction with the tungsten-containing gas and the reducing agent. This controlled depletion can produce a non-uniform tungsten nitride passivation layer that is thicker proximate (e.g., near) a top portion of the opening(s) than at a lower portion thereof. Such a steep passivation gradient ensures that subsequent tungsten gapfill material, deposited at block 306, nucleates from the bottom up. In addition, the elevated hydrogen in the gas GSD mixture reduces fluorine-induced etching and stabilizes the film chemistry, broadening the process window so higher concentrations of nitrogen-containing gas can be used without undesired etching from fluorine byproducts (e.g., reducing etch sensitivity of the GSD profile, particularly at the temperature utilized for bulk deposition).

At block 306, a first bulk deposition of tungsten-containing gapfill material is performed. The tungsten-containing material is deposited, at least partially, into the opening(s) of the substrate 230, now lined with the tungsten nitride passivation layer.

In some embodiments, the tungsten-containing material is deposited using a chemical vapor deposition (CVD) process comprising concurrently flowing (co-flowing) a tungsten-containing gas and a gapfill reducing agent, such as hydrogen (H₂), into the processing region 221 and exposing the substrate 230 thereto. Examples of suitable tungsten-containing gases include tungsten halides, such as tungsten hexafluoride (WF₆), tungsten hexachloride (WCl₆), or combinations thereof. In some embodiments, the tungsten-containing precursor includes WF₆, and the nucleation reducing agent includes H₂. In some embodiments, the tungsten-containing material only partially fills the opening(s) in the substrate 230 during the first bulk deposition at block 306. In such embodiments, the remainder of the opening(s) can be filled with tungsten-containing material during subsequent repetitions of block 306, and/or during performance of a second bulk deposition at block 310.

In some embodiments, the tungsten-containing gas at block 306 can be flowed into the processing region 221 at a flow rate of between about 10 sccm and about 1200 sccm, or more than about 50 sccm, or less than about 1000 sccm, or between about 100 sccm and about 900 sccm, or between about 150 sccm and about 600 sccm.

In some embodiments, the gapfill reducing agent gas, such as hydrogen (H₂) gas, is flowed into the processing region 221 at block 306 at a flow rate of about 1000 sccm to about 9000 sccm, such as about 2000 sccm to about 8000 sccm, such as about 3000 sccm to about 7000 sccm, such as about 4000 sccm to about 6000 sccm. In some embodiments, the gapfill reducing agent is flowed into the processing chamber between about 6000 sccm and about 8000 sccm. In some embodiments, the gapfill reducing agent is flowed into the processing chamber between about 1500 sccm and about 3000 sccm. In some embodiments, the gapfill reducing agent gas is flowed into the processing region 221 at a rate of about 1000 sccm or more, such as about 5000 sccm or more.

In some embodiments, as shown in FIG. 3B, the gapfill reducing agent gas is flowed into the processing region 221 at an increased flow rate for at least a first portion 306A of the bulk deposition operation at block 306 to create a reducing agent-rich (e.g., hydrogen-rich) ambient, followed by a second portion 306B of the bulk deposition operation with a reduced flow rate of the gapfill reducing agent gas. In such embodiments, the first portion 306A of block 306 can be referred to as an “etch suppression” operation, as the increased flow and presence of hydrogen (or other gapfill reducing agent gas) in the processing volume 221 suppresses unwanted etching of the deposited tungsten nitride passivation layer by residual fluorine from the nitrogen-containing gas in the processing chamber 221. This etch suppression removes residual fluorine, stabilizes the tungsten film surface, and controls etching.

In embodiments where etch suppression is performed, hydrogen (or other gapfill reducing agent gas) can be flowed into the processing region 221 during the first portion 306A at a flow rate of greater than about 5000 sccm (5 SLM), such as about 6000 sccm (6 SLM) or more, such as about 7000 sccm (7 SLM) or more, such as about 8000 (8 SLM) sccm or more, or about 9000 (9 SLM) sccm or more. In some embodiments, the hydrogen or other gapfill reducing agent gas is flowed into the processing region 221 during the first portion 306A at a flow rate of about 6000 sccm and about 8000 sccm. During the second portion 306B, hydrogen (or other gapfill reducing agent gas) can be flowed into the processing region 221 at a flow rate of less than about 6000 sccm, such as about 5000 sccm or less, such as about 4000 (4 SLM) sccm or less, such as about 3000 sccm (3 SLM) or less, such as about 2000 sccm (2 SLM) or less, or about 1500 sccm (1.5 SLM) or less. In some embodiments, the hydrogen or other gapfill reducing agent gas is flowed into the processing region 221 during the first portion 306B at a flow rate of about 1500 sccm and about 3000 sccm. In some embodiments, the ratio of hydrogen (or other gapfill reducing agent gas) flow rates between the first portion 306A and 306B is between about 2:1 to about 6:1. Generally, the flow rate of the tungsten-containing gas remains constant between the first portion 306A and the second portion 306B of block 306.

In some embodiments, the flow rate of the gapfill reducing agent gas at portion 306A is equal to or greater than the flow rate thereof during the GSD treatment at block 304. The duration of the first portion 306A of block 306 can be between about 1 second and about 20 seconds or more, such as between about 5 seconds and about 20 seconds or more, such as between about 10 seconds and about 15 seconds or more. Meanwhile, the duration of the second portion 306B can vary depending on a selected structure or growth rate of the tungsten-containing material.

In some embodiments, CVD process conditions at block 306 are selected to provide a tungsten feature having a relativity low residual film stress when compared to conventional tungsten CVD processes. For example, in some embodiments, the CVD process includes heating the substrate to a temperature of about 250 °C or more, such as about 300 °C or more, or between about 250 °C and about 600 °C, or between about 300 °C and about 500 °C. During the CVD process, the processing volume 221 is typically maintained at a pressure of less than about 500 Torr, less than about 600 Torr, less than about 500 Torr, less than about 400 Torr, or between about 1 Torr and about 500 Torr, such as between about 1 Torr and about 450 Torr, or between about 1 Torr and about 400 Torr, or for example, between about 15 Torr and about 300 Torr.

In some embodiments, tungsten-containing material is deposited into the opening(s) of the substrate 230 at block 306 using an atomic layer deposition (ALD) process. A tungsten gapfill ALD process includes repeating cycles of alternately exposing the substrate 230 to a tungsten-containing gas and a gapfill reducing agent and purging the processing region 221 between the alternating exposures. The tungsten-containing gas and the gapfill reducing agent are each flowed into the processing region 221 for a duration of between about 0.1 seconds and about 10 seconds, such as between about 0.5 seconds and about 5 seconds. The processing region 221 is typically purged between the alternating exposures by flowing an inert purge gas, such as argon (Ar) or hydrogen, into the processing region 221 for a duration of between about 0.1 seconds and about 10 seconds, such as between about 0.5 seconds and about 5 seconds. The purge gas may be delivered from the deposition gas source 240 or from a bypass gas source (not shown).

In other embodiments, tungsten gapfill material is deposited at block 306 using a pulsed CVD method that includes repeating cycles of alternately exposing the substrate 230 to a tungsten-containing gas and a gapfill reducing agent without purging the processing region 221. The processing conditions for tungsten gapfill pulsed CVD can be the same, substantially the same, or within the same ranges as those described above for a tungsten gapfill ALD process.

At block 308, the substrate 230 is exposed to an intermediary hydrogen soak between bulk deposition operations. Performance of the hydrogen soak removes any fluorine residues remaining from the GSD treatment and/or first bulk deposition process, thereby further suppressing and/or eliminating unwanted etching of deposited tungsten gapfill material. For example, the hydrogen soak at block 308 can remove 50% or more, such as 75% or more, of surface fluorine on the deposited tungsten-containing material. Moreover, exposure to a hydrogen-rich environment facilitates control of tungsten grain structure and gapfill resistivity, and improved film adhesion. As hydrogen interacts with a developing tungsten film surface, it can influence nucleation sites, grain size distribution, and overall film morphology, thus offering a greater degree of tunability in achieving desired electrical and mechanical properties for deposited tungsten gapfill materials.

During block 308, the substrate 230 is maintained at a temperature of about 300 °C to about 500 °C while hydrogen (e.g., H2) is flowed into the processing volume 221 at a flow rate of about 5000 sccm or more, with little to no flow of tungsten-containing gas. In some embodiments, the hydrogen is flowed into the processing volume 221 at a flow rate of about 6000 sccm or more, such as about 7000 sccm or more, such as about 8000 or more, or about 9000 sccm or more. The hydrogen soak at block 308 can have a duration of about 30 to about 360 seconds or more, such as between about 60 seconds and about 180 seconds or more.

At block 310, a second bulk deposition of tungsten-containing gapfill material is performed to deposit additional tungsten-containing gapfill material in the opening(s). In some embodiments, the second bulk deposition fills the remaining empty volume of opening(s) of the substrate 230 with tungsten-containing material. In some embodiments, the second bulk deposition includes depositing an overburden layer of tungsten-containing material into the opening(s) and onto a field surface of the substrate 230. A chemical mechanical polishing (CMP) process can be used thereafter to remove the overburden of tungsten-containing material (and any barrier and/or adhesion layer(s) disposed there below) from the field surface of the substrate 230.

In some embodiments, the second bulk deposition at block 310 is substantially similar to the first bulk deposition at block 306, and utilizes the same or similar process parameters. In some embodiments, the second bulk deposition utilizes different process parameters as compared to the first bulk deposition. For example, in some embodiments, the first bulk deposition of block 306 can include the first portion 306A and the second portion 306B with varying hydrogen flow parameters, while the second bulk deposition at block 310 includes only a single portion having process parameters similar to those during the second portion of 306B. In other words, in some embodiments, the first bulk deposition at block 306 can include etch suppression (first portion 306A), while the second bulk deposition at block 310 does not.

As noted above, one or more of blocks 302, 304, 306, 308, and/or 310 can be iteratively repeated, individually or in combination, during the process flow 300A, as indicated by arrows 320, 322, and 324. For example, in some embodiments, as indicated by arrow 320, after performing blocks 302-306, a sequence of both blocks 304 and 306 can be iteratively repeated for two or more iterations, such as for three, four, five, or more iterations, until a desired amount of tungsten-containing material is deposited in the opening(s) of the substrate 230 before performance of the hydrogen soak at block 308. In some embodiments, as indicated by arrow 322, after performing blocks 302-306, a sequence of all three blocks 302-306 can be iteratively repeated for two or more iterations, such as for three, four, five, or more iterations, until a desired amount of tungsten-containing material is deposited in the opening(s) of the substrate 230 before performance of the hydrogen soak at block 308. In some embodiments, as indicated by arrow 324, after performing blocks 302-308, a sequence of all three blocks 304-308 can be iteratively repeated for two or more iterations, such as for three, four, five, or more iterations, before performance of the second bulk deposition at block 310. Where blocks 304 and 304 are iteratively repeated, subsequent iterations may or may not include etch suppression.

In some embodiments, the complete sequence of the process flow 300A can be optionally performed entirely in-situ within a single processing chamber (e.g., processing chamber 200). In some embodiments, two or more blocks of the process flow 300A are performed in different processing chambers.

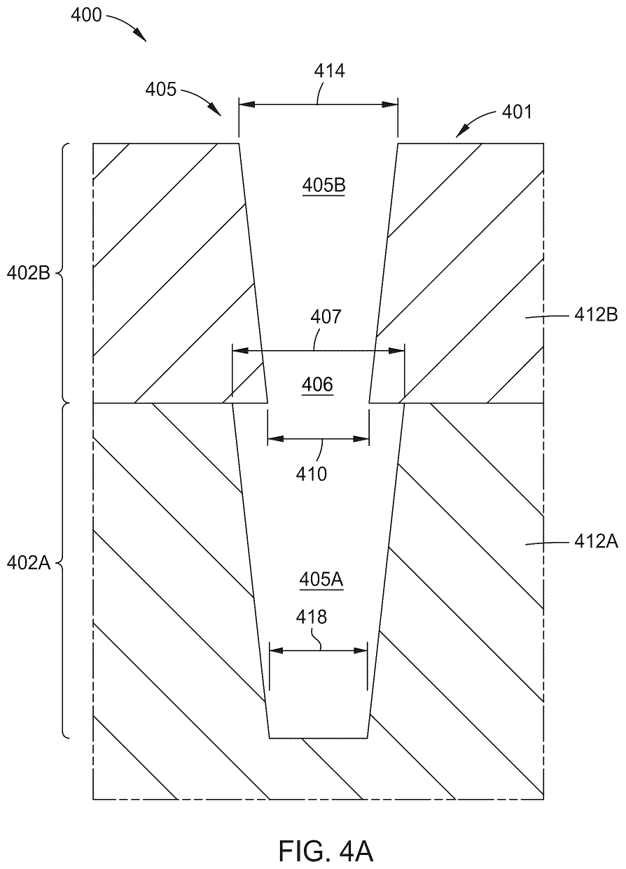

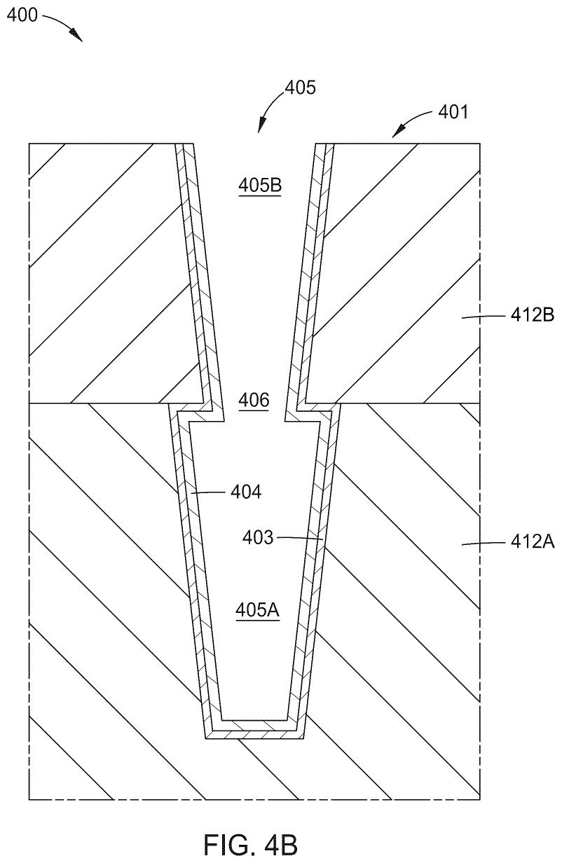

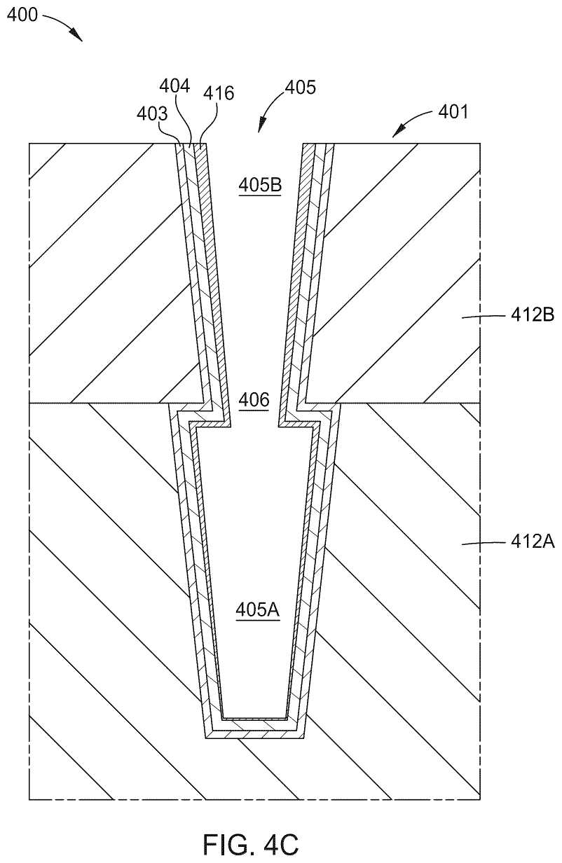

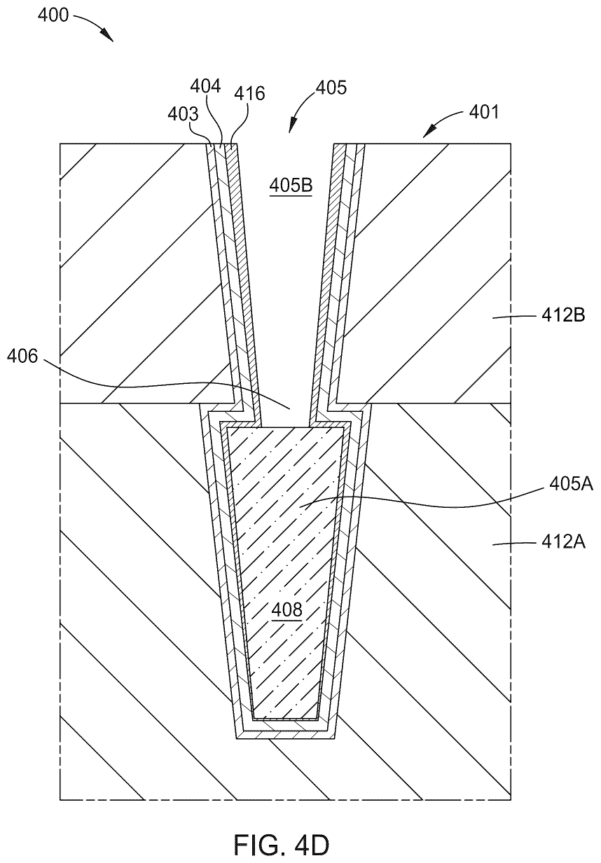

FIGS. 4A-4D are schematic sectional views of a portion of a substrate 400 illustrating aspects at different stages of the process flow 300A if FIG. 3A. FIGS. 4A-4D demonstrate how controlled hydrogen flow, hydrogen soak intervals, and non-uniform passivation layers enable bottom-up tungsten deposition with reduced voids, improved adhesion, and tunable grain characteristics, thereby achieving more reliable tungsten features even in challenging multi-tier and high aspect ratio structures.

With reference to FIG. 4A, the substrate 400 includes a patterned surface 401 having a first tier layer 412A and a second tier layer 412B having a plurality of openings 405 (one shown) formed therein. A portion of the opening 405 disposed within the first tier layer 412A can be referred to as a first tier opening 405A, and a portion of the opening 405 disposed within the second tier layer 412B can be referred to as a second tier opening 402B. The first and second tier openings 405A, 405B together form the single contiguous opening 405. The uppermost portion of the first tier opening 405A interfaces the lowermost portion of the second tier opening 405B at an interface 406.

In some embodiments, the plurality of openings 405 include one or more high aspect ratio via and/or trench openings having a width (e.g., a width 407 of first tier opening 405A and/or a width 414 of second tier opening 405B) of about 50 nm to about 500 nm, such as about 100 nm to about 400 nm and a depth (e.g., of one or both of the first tier opening 402A or the second tier opening 402B) of about 2 μm to about 20 μm, such as about 15 μm to about 20 μm. In some embodiments, the plurality of openings 405 includes at least one opening with a width 410 of a narrowest portion of the opening 405 of about 50 nm to about 200 nm, such as about 75 nm to about 125 nm. In some embodiments, individual openings 405 may have an aspect ratio (depth to width ratio) of about 10:1 or more, such as about 25:1 or more, such as about 30:1 to about 100:1, such as about 40:1 to about 60:1, such as about 50:1, or more. In some embodiments, the vias or trench openings include aspect ratios of about 20:1 to about 40:1.

In some embodiments, the width 407 of an uppermost portion of the first tier opening 405A is greater than the width 410 of the lowermost portion of the second tier opening 405B at the interface 406, and/or greater than a width 418 of a lowermost portion of the first tier opening 405A. In some embodiments, the width 407 is about 5% to about 100% greater than the width 410, such as about 10% greater to about 50% greater. For example, width 410 can be about 50 nm to about 300 nm, such as about 75 nm to about 125 nm and the width of 407 can be about 70 nm to about 400 nm, such as about 150 nm to about 250 nm. Alternatively, the width of 407 of the uppermost portion of the first tier opening 405A is less than the width 410 of the lowermost portion of the second tier opening 405B at the interface 406. In some embodiments, for each tier, a widest portion of the tier, such as the width 414 of the second tier layer 412B, is about 5% to about 100% greater than a narrowest portion of the tier, such as the width 410 of the second tier layer 412B, such as about 10% greater to about 50% greater. In some embodiments, a height of the first tier opening 405A is substantially the same, is less than, or greater than a height of the second tier opening 405B. Without being bound by theory, it is believed that sudden differences in opening widths at interfaces can cause a pinching effect during gapfill material deposition. The methods described herein enables a growth behavior that fills openings without the formation of voids.

Referring now to FIG. 4B, the substrate is shown after performance of at least one iteration of block 302 of the process flow 300A, wherein a nucleation layer 404 is formed over sidewalls of the opening 405. In the example shown, the nucleation layer 404 is formed over a barrier or adhesion layer 403, e.g., a titanium nitride (TiN) layer. The barrier or adhesion layer 403 is deposited on the first tier layer 412A and the second tier layer 412B in a preceding operation prior to block 302 to conformally line the opening 405 and facilitate the subsequent deposition of the tungsten nucleation layer 404. In some embodiments, the adhesion layer 403 is deposited to a thickness of between about 20 angstroms (Å) and about 150 Å, such as about 30 Å to about 100 Å. In some embodiments, the nucleation layer 404 has a thickness of between about 10 Å and about 200 Å, such as between about 10 Å and about 150 Å, or between about 20 Å and about 150 Å. In FIG. 4B, the opening 405 is shown before performance of a GSD treatment, thereby illustrating the manner in which barrier or adhesion layer 403 and nucleation layer 404 conform to the contours of the opening 405.

FIG. 4C illustrates the substrate 400 after performance of at least a first GSD treatment of block 304 of the process flow 300A, but prior to bulk deposition of any tungsten-containing gapfill material. During the GSD treatment, a nitrogen-containing gas gradient is formed within the opening 405 that results in a non-uniform tungsten nitride passivation layer 416 that is thicker towards a top portion second tier opening 405B and thinner at a lower portion of the first tier opening 405A. Such a passivation layer gradient promotes nucleation of the subsequent tungsten gapfill material, deposited at block 306, from the bottom up. Consequently, when the tungsten-containing gapfill material is ultimately deposited, it will initiate more readily near the lower regions of the opening 405, mitigating pinch-off or void formation at, e.g., the interface 406. In addition, the elevated hydrogen in the gas GSD mixture during block 304 reduces fluorine-induced etching and stabilizes the film chemistry.

FIG. 4D shows the substrate 400 after at least blocks 306 and 308 are performed at least once, and in certain embodiments, after block 310 has been performed at least once. As shown, tungsten-containing material 408 has been deposited into the opening 405, where it first begins accumulating near the bottom of the opening 405 (e.g., in first tier opening 405). The varying thickness of the passivation layer 416 serves to direct tungsten deposition at lower regions first, before growing in upper regions. Consequently, the tungsten-containing material 408 fills upward, avoiding pinch-off at, e.g., the interface 406, and helping to maintain a continuous seam-free deposit.

After at least an initial bulk deposition is performed at block 306, a hydrogen soak is performed at block 308 to remove additional fluorine, improve adhesion between newly deposited tungsten-containing material 408 and underlying layers, and allow fine control over the tungsten grain size and resistivity. In some embodiments, a longer soak duration can be used after a partial fill stage to yield smaller grains that enhance mechanical stability, while a shorter soak duration might preserve larger grains and thus lower resistivity.

As the fill progresses, additional cycles of blocks 302, 304, 306, 308, and/or 310 can be performed to continue to build the tungsten-containing material 408 from first tier layer 405A to first tier layer 405B, and/or an overburden layer, achieving reliable bottom-up fill even in high aspect ratio or multi-tier architectures.

Accordingly, methods for forming tungsten-containing structures within high aspect ratio openings of multi-tier semiconductor devices are provided herein. In one aspect, a substrate having narrow, deep openings is first exposed to a tungsten nucleation process, establishing a uniform nucleation layer. A passivation step follows, co-flowing a nitrogen-containing gas, a tungsten-containing precursor, and hydrogen at increased flow rates to form a non-uniform tungsten nitride layer that promotes bottom-up tungsten deposition and reduces fluorine-related etching. Bulk tungsten deposition then proceeds from deeper regions upward, minimizing voids and seams. An intermediary hydrogen soak step is performed mid-deposition to remove residual fluorine, enhance film adhesion, and refine grain size or lower resistivity. The present methods deliver robust tungsten features with improved mechanical integrity and electrical performance, even in challenging 3D NAND and similarly complex architectures.

When introducing elements of the present disclosure or exemplary aspects or embodiments thereof, the articles “a,” “an,” “the” and “said” are intended to mean that there are one or more of the elements.

The terms “comprising,” “including” and “having” are intended to be inclusive and mean that there may be additional elements other than the listed elements.

The term “coupled” is used herein to refer to the direct or indirect coupling between two objects. For example, if object A physically touches object B and object B touches object C, the objects A and C may still be considered coupled to one another—even if objects A and C do not directly physically touch each other. For instance, a first object may be coupled to a second object even though the first object is never directly in physical contact with the second object.

While the foregoing is directed to embodiments of the present disclosure, other and further embodiments of the disclosure may be devised without departing from the basic scope thereof, and the scope thereof is determined by the claims that follow.

1. A method of forming a tungsten-containing structure in at least one opening of a multi-tier substrate in a processing chamber, comprising:
depositing a tungsten nucleation layer on surfaces of the at least one opening;
exposing the at least one opening to a nitrogen-containing gas, a tungsten-containing gas, and a hydrogen-containing gapfill reducing agent gas to form a non-uniform passivation layer over the tungsten nucleation layer, wherein the at least one opening is exposed to the nitrogen-containing gas, the tungsten-containing gas, and the hydrogen-containing gapfill reducing agent gas simultaneously;
exposing the at least one opening to a hydrogen-rich ambient; and
depositing a tungsten-containing material over the non-uniform passivation layer.

2. The method of claim 1, wherein:
the nitrogen-containing gas is flowed into the processing chamber at about 0.5 sccm to about 500 sccm;
the tungsten-containing gas is flowed into the processing chamber at about 150 sccm to about 600 sccm; and
the hydrogen-containing gapfill reducing agent gas is flowed into the processing chamber at about 1000 sccm to about 8000 sccm.

3. The method of claim 1, wherein exposing the at least one opening to the hydrogen-rich ambient comprises:
exposing the at least one opening to an intermediary hydrogen soak between a first deposition of the tungsten-containing material and a second deposition of the tungsten-containing material.

4. The method of claim 1, wherein exposing the at least one opening to the hydrogen-rich ambient comprises:
exposing the at least one opening to the hydrogen-rich ambient during the deposition of the tungsten-containing material to suppress etching of the non-uniform passivation layer by residual fluorine from the nitrogen-containing gas or the tungsten-containing gas.

5. The method of claim 4, wherein the non-uniform passivation layer comprises tungsten nitride.

6. The method of claim 1, wherein the at least one opening comprises:
a first portion having a first width at a first depth and a second width at a second depth; and
a second portion above the first portion, and having a third width at the second depth and a fourth width at a third depth, wherein the second width is less than the third width and the fourth width is less than the third width.

7. The method of claim 6, wherein the non-uniform passivation layer is thicker proximate the second portion than the first portion.

8. The method of claim 1, wherein the tungsten-containing gas comprises tungsten fluoride (WF₆) and the hydrogen-containing gapfill reducing agent gas comprises hydrogen (H₂).

9. The method of claim 1, wherein the nitrogen-containing gas is selected from the group consisting of NF₃, NH₃, N₂H₄, and combinations thereof.

10. The method of claim 1, wherein forming the non-uniform passivation layer further comprises:
maintaining the multi-tier substrate at a temperature between about 300 °C and about 500 °C; and
maintaining the processing chamber at a pressure of about 15 Torr to 150 Torr.

11. A system for forming a tungsten-containing structure within at least one high aspect ratio feature of a substrate, the system comprising:
a processing chamber configured to hold the substrate having the at least one high aspect ratio feature;
a gas delivery system coupled to the processing chamber; and
a system controller coupled to the processing chamber and the gas delivery system, the system controller being programmed to cause the processing chamber and gas delivery system to:
deposit a tungsten nucleation layer on surfaces of the at least one opening;
expose the at least one opening to a nitrogen-containing gas, a tungsten-containing gas, and a hydrogen-containing gapfill reducing agent gas to form a non-uniform passivation layer over the tungsten nucleation layer, wherein:
the nitrogen-containing gas is flowed into the processing chamber at about 0.5 sccm to about 500 sccm;
the tungsten-containing gas is flowed into the processing chamber at about 150 sccm to about 600 sccm; and
the hydrogen-containing gapfill reducing agent gas is flowed into the processing chamber at about 1000 sccm to about 8000 sccm;
exposing the at least one opening to a hydrogen-rich ambient; and
deposit a tungsten-containing material over the non-uniform passivation layer.

12. The system of claim 11, wherein exposing the at least one opening to the hydrogen-rich ambient comprises:
exposing the at least one opening to an intermediary hydrogen soak between a first deposition of the tungsten-containing material and a second deposition of the tungsten-containing material.

13. The system of claim 12, wherein exposing the at least one opening to the intermediary hydrogen soak comprises:
flowing hydrogen into the processing chamber at about 5000 sccm or more for a duration of about 30 seconds to about 360 seconds.

14. The system of claim 11, wherein exposing the at least one opening to the hydrogen-rich ambient comprises:
exposing the at least one opening to the hydrogen-rich ambient during the deposition of the tungsten-containing material to suppress etching of the non-uniform passivation layer by residual fluorine from the nitrogen-containing gas or the tungsten-containing gas.

15. The system of claim 14, wherein the non-uniform passivation layer comprises tungsten nitride.

16. The system of claim 11, wherein the at least one opening comprises:
a first portion having a first width at a first depth and a second width at a second depth; and
a second portion above the first portion, and having a third width at the second depth and a fourth width at a third depth, wherein the second width is less than the third width and the fourth width is less than the third width.

17. The system of claim 16, wherein the non-uniform passivation layer is thicker proximate the second portion than the first portion.

18. The system of claim 11, wherein the tungsten-containing gas comprises tungsten fluoride (WF₆) and the hydrogen-containing gapfill reducing agent gas comprises hydrogen (H₂).

19. The system of claim 11, wherein the nitrogen-containing gas is selected from the group consisting of NF₃, NH₃, N₂H₄, and combinations thereof.

20. A method of forming a tungsten-containing structure in at least one opening of a multi-tier substrate in a processing chamber, comprising:
depositing a tungsten nucleation layer on surfaces of the at least one opening;
forming a passivation layer over the tungsten nucleation layer, wherein the passivation layer is thicker at a top portion of the at least one opening than at a bottom portion of the at least one opening;
depositing a tungsten-containing material over the passivation layer;
exposing the tungsten-containing material to a hydrogen-rich ambient; and
depositing additional tungsten-containing material into the at least one opening.
